(19) United States
(12) Patent Application Publication
(10) Pub. No.: US 2011/0209761 A1
(43) Pub. Date: Sep. 1, 2011

(54) GLAZING WITH LIGHT-CONCENTRATING ZONES BY ION EXCHANGE

(75) Inventors: Guillaume Counil, Aubervilliers (FR); Michele Schiavoni, Paris (FR); Arnaud Huignard, Compiegne (FR); Julien Sellier, Paris (FR); Xavier Brajer, Cormeilles-en-Parisis (FR)

(73) Assignee: SAINT-GOBAIN GLASS FRANCE, Courbevoie (FR)

(21) Appl. No.: 13/127,377

(22) PCT Filed: Nov. 2, 2009
(86) PCT No.: PCT/FR09/52113

§ 371 Date: May 3, 2011

(30) Foreign Application Priority Data
Nov. 3, 2008 (FR) 0857446

(51) Int. Cl. H01L 31/0232; C03C 21/00

(52) U.S. Cl. 136/259; 65/30.13

(57) ABSTRACT

This flat mineral glass comprises a first free surface and a second free surface, and comprises groups of zones having a high refractive index (n₂) and zones having a low refractive index (n₁) which are formed in the thickness of the flat glass between the first and second free surfaces, over a depth of between 1 and 1000 μm starting from the first free surface. These high-index zones and low-index zones alternate along a direction transverse to the thickness direction of the glass between the first and second free surfaces, the high-index zones flaring out from the first free surface toward the second free surface, and the envelope surfaces of the high-index zones making an angle (θ) of at least 65° with respect to the first free surface.

The invention relates to the field of solar concentrators for photovoltaic systems that make it possible to collect an equivalent amount of light energy for a smaller area of active layer. The device forming the subject of the invention profits from the phenomenon of total light reflection within concentrators produced by means of a substrate having a glass function, the objective being to reflect all of the light toward zones covered with a functional active layer for energy conversion from light energy to electrical energy, within photovoltaic cells.

Among the various photovoltaic cell technologies, the technology based on single-crystal or polycrystalline silicon wafers is greatly predominant, with about 95% market share. Moreover, it should be pointed out that a number of thin-film technologies (amorphous Si, CIS, CdTe, etc.) are being developed with relatively advantageous energy efficiencies and fabrication costs.

It is known that the amount of energy generated by a photovoltaic device is influenced by various factors and most particularly by the amount of solar energy absorbed by a module, the conversion efficiency of the cells contained in said module and the intensity of the light striking the module. Considerable research is currently being conducted in order to improve the technology specific to each of these aspects.

Furthermore, the total amount of energy generated by the device is of course directly proportional to the area covered by the device, and more precisely by the accumulative area covered by all of the photovoltaic cells incorporated in the conversion system. Thus, the amount of energy but also the investment costs are at the present time directly proportional to the size of the installation.

More particularly, the main element that currently limits even greater growth is the cost and the quality of the silicon used in the fabrication of photovoltaic cells, for which the solar energy market is the greatest outlet. Most particularly, this explains the fact that the cost of an installation now is increasing not primarily as a function of the overall size of the installation, but above all as a function of the portion covered by the photovoltaic cells themselves.

In this context, one approach already described consists in producing large-area solar modules incorporating a textured substrate which concentrates the light onto smaller-area cells. In these modules, for substantially the same dimensions of the device and a substantially equivalent amount of received energy, by introducing light concentrators it is possible for the intrinsic area of the photovoltaic cells to be substantially reduced, thereby lowering the overall cost of the installation.

Patent application WO 2006/133126 or application US 2006/272698 describe possible embodiments of a textured substrate acting as light concentrator.

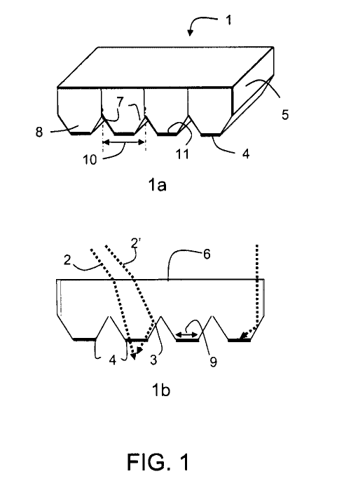

To illustrate the operating principles of this type of light concentrator, FIG. 1a and FIG. 1b show schematically a perspective view and a sectional view, respectively, of said light concentrator.

Thus, a photovoltaic module 1 is formed from a series of elementary photovoltaic cells 4 in the form of bands bonded to a glass substrate 5. The substrate 5 has a two-dimensional texturing feature 7, as shown in FIG. 1a, configured so as to enable the light to be trapped.

More particularly, the texturing feature 7 may be described as consisting of a succession of mutually parallel triangular prisms 8, the ends of which are truncated, in such a way that the substrate has, on its inside, a plane band 11, the area of which corresponds to that of the photovoltaic band 4 placed facing it.

The operating principle can be readily understood by considering the path of the rays 2 and 2′ as shown in FIG. 1b. The two rays are refracted at the air-glass interface 6. The refracted ray 2 arrives directly on the photovoltaic cell 4, whereas the ray 2′ undergoes a total internal reflection at the point 3, before reaching the cell 4. A person skilled in the art will thus readily understand that the rays making even relatively high angles of incidence to the normal to the surface of the substrate 5 will nevertheless be collected by the photovoltaic cells, thereby concentrating the light in accordance with the present invention. A concentration factor may also be easily calculated, corresponding to the ratio of the spacing between two successive texturing features to the width of the photovoltaic cells, i.e. the width 9 of the band 11. The term “spacing” according to the present invention corresponds to the pitch of the texturing feature, or else to the distance between the median positions of two successive cells.

Furthermore, the angle of reception of the light rays may be substantially increased by texturing with reliefs similar to those described in relation to FIG. 1a or FIG. 1b, but with round sidewalls. Parabolic sidewalls appear to be very effective in trapping the light.

Among the various materials that can be used for the substrate 5, a mineral glass has many advantages, in particular with regard to its stability over the course of time and its great temperature resistance and UV resistance for example. A glass with a low iron content is preferred, in order to minimize absorption, in particular the glass Albarino® from the company Saint-Gobain Glass.

The disadvantage of this prior art stems from the fact that, in order for the system to operate correctly, a wedge of air (or of a vacuum or of any gas) must be left between two adjacent truncated prisms. This may cause:
fabrication difficulties, since in general the modules are laminated and during lamination all the air bubbles are eliminated;
poor aging of the module (delamination, which will start at the air wedge, corrosion of the cell, etc.); and
substantial difficulties during precise fabrication of such a textured plate (the standard methods, such as glass rolling process, are not very precise).

The object of the invention is therefore to replace this textured glass substrate with a flat glass substrate having an alternation of zones of low refractive index n₁ and zones of high refractive index n₂, the index difference n₂−n₁ being equal to or greater than 0.1.

According to the present invention, zones with a high light refraction index are created starting from the free surface of the glass that does not receive the solar flux. These zones having a high refractive index n₂ are separated from one another by zones having a low refractive index n₁. The high-index zones, spaced apart with a constant period, merge either on a plane within the glazing or at the free surface of the glazing that receives the solar flux. Thus, an optical convergence device, usually referred to as an optical concentrator, is formed in the high-index zones, thereby making it possible to concentrate light rays at the free surface of the glass that does not receive the solar flux, opposite which surface a functional element of a solar or photovoltaic module will advantageously be placed, enabling the light energy to be transformed to electrical energy.

For this purpose, one subject of the present invention is a flat mineral glass comprising a first free surface and a second free surface, and comprising groups of zones having a high refractive index and zones having a low refractive index which are formed in the thickness of the flat glass between the first and second free surfaces, over a depth of between 1 and 1000 μm starting from the first free surface, said high-index zones and low-index zones alternating along a direction transverse to the thickness direction of the flat glass between the first and second free surfaces, the high-index zones flaring out from the first free surface toward the second free surface, and the envelope surfaces of the high-index zones making an angle of at least 65°, preferably substantially close to 70°, with respect to the first free surface.

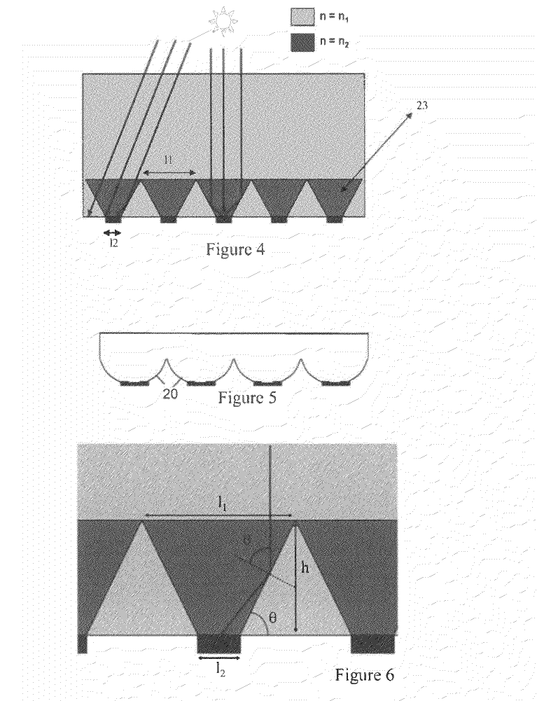

According to a first embodiment of the invention, the glass comprises in its thickness an alternation of high-index zones, the envelope of each of which forms a trapezoid and, in the volume, a trapezoid-based prism. The zones alternate in two intersecting directions, as illustrated for example in FIG. 4. In other words, according to this first embodiment, the high-index zones are trapezoid-based prisms having a small base of length l₂ and a large base of length l₁, said prisms being formed over all or parts of the thickness of the glass. Advantageously, the high-index zones have a depth in the glass starting from the first free surface of between 20 μm and 700 μm.

According to another embodiment of the invention, the high-index zones may also have sidewalls or an envelope of rounded or spherical shape, as illustrated in FIG. 5.

Whatever the embodiment of the invention, the refractive index difference, between the index of each low-index zone and the index of each high-index zone, is between 0.05 and 0.15, and more particularly between 0.10 and 0.15. In addition, the concentration ratio l₂/l₁ is between 35 and 55%, and preferably close to 40%.

The high-index and low-index zones differ by the content of at least one cationic element. The term “cationic element” is understood to mean an element whose ionic form is positive. For example, the ionic form of a sodium atom is the cation Na⁺. Likewise, the ionic form of a silver atom is the cation Ag⁺. In a mineral glass, the cationic element is in oxide form and its bonds to oxygen atoms are partially ionic and partially covalent. The high-index zones may in particular contain at least one element from the group: Ag, Tl, Cu, Ba.

The glass according to the invention may be used to collect light incident on a solar cell. In particular, the glass according to the invention may form a solar concentrator provided with silicon bands and may be incorporated into a photovoltaic module.

The free surface of the glass that receives the solar flux is plane. The glass according to the invention is monolithic since it consists of a single glass matrix, the composition of which has been locally modified in the high refractive index zones by ion exchange.

These zones are created by ion exchange between at least one element contained in the glass and at least one element introduced via a medium placed in contact with the glass. In particular, sodium atoms contained in the glass may be exchanged with silver atoms introduced by a silver salt, or by thallium atoms introduced by a thallium salt, brought into contact with the glass. In particular, the silver salt may be silver nitrate AgNO₃ and the thallium salt may be thallium nitrate TlNO₃. The sodium leaves the glass to form a sodium derivative.

This ion exchange creates, in the thickness of the glass, an alternation of different media having different refractive indices without modifying the initial relief of the surface of the glass. This ion exchange is carried out by migration in an electric field, thereby making it possible to obtain step-index zones of controlled shape. In particular, these zones may advantageously be of trapezoidal shape or partially spherical or rounded, as explained above. Thus, if the glass is smooth before ion exchange, it is still smooth after ion exchange.

To produce an alternation of trapezoidal zones, that surface of the glass opposite from the face receiving the solar flux is brought into contact with an alternation of two materials acting as sources of ions to migrate into the glass in order to create said zones. These materials are deposited in the form of bands having a profile matched or conforming to that which it is desired to obtain after the ions have diffused. Thus, to obtain trapezoid-shaped zones, it is necessary to use bands of material having a trapezoidal profile. In the volume, these zones define trapezoid-based prisms.

The invention thus also relates to a process for fabricating a glass, comprising the bringing of a glass, initially with no zones, into contact with an alternation of bands of two different ion source materials providing different ions that can migrate into the glass under the effect of an electric field, and comprising the application of an electric field. The zones are created beneath the bands of the two materials. The geometry of the surface of the zones on the surface of the glass corresponds to the geometry of the surface of contact of the materials with the glass. The alternating zones created in the glass are enriched with the ionic element coming from the material that was directly above it. To create this alternation, the source material providing the high-polarizability ion, i.e. the source material providing the ion that will form part of the composition of the high-index zone, is in solid form, generally an enamel or a metal such as silver, and placed in the form of bands on the surface of the glass, it being possible for the other material to be in liquid or solid form. This other material, namely the source material providing the lower-polarizability ion that will enter the low-index zone, fills the space between the bands of the first material. If the other material is solid, it is also placed in the form of bands between those of the first material. If the other material is liquid, it fills the space between the solid bands of the first material. The high-polarizability ion is an element of the following group: Ag, Ba, Tl, Cu. As regards the lower-polarizability element, this is chosen from: Li, Na, K, Ca, Sr. The greater the difference in polarizabilities of the ions in the alternating zones, the greater the difference between the refractive indices, this being preferable for redirecting rays incident at higher angles of incidence.

According to one embodiment, the first material is solid and of the metal type, such as silver, thallium, copper, or of the enamel type containing at least one of the elements of the group: Ag, Ba, Tl, Cu. The other material may also be solid and of the enamel type containing at least one of the elements of the group: Li, Na, K, Ca, Sr, while being different from the first material. It may also be liquid, generally of the molten salt type, such as KNO₃, LiNO₃, Ca or BaTFSI (where TFSI stands for bis(trifluoromethanesulfonyl)imide), etc.

Advantageously, the two alternating materials on the surface of the glass are sources of cationic elements of equivalent mobility, thereby preventing the field lines from being distorted during migration and therefore enabling the ions to migrate perpendicular to the surface of the glass. This mobility may be determined by measuring the rate of penetration of an ion into a glass under given (temperature, glass matrix) conditions. The penetration depth may be readily determined by observation under a scanning electron microscope or by weight uptake of the substrate. Since the electric field lines are not distorted, the shape of the material containing the high-polarizability element is reproduced in the glass during electric-field-assisted ion exchange, to within a proportionality factor. Thus, if the material is a band of trapezoidal shape, the high-index zone obtained after exchange is also a band of trapezoidal shape.

The migration of the cationic elements under the electric field is performed for a time long enough for the zones created in the glass to have the desired depth, i.e. the intended depth in the glass starting from the first free surface.

For example, the solid material may be an enamel of the element intended to diffuse. This enamel is generally produced from a frit deposited by screen printing. After ionic exchange, the solid material is removed, for example by polishing or by acid etching.

If the material containing the ion entering the low-index zone is liquid, the process may include an additional step that consists in applying a protective film on the solid material before being brought into contact with the liquid material. The function of the protective film is to prevent the cationic element of the liquid material from migrating into the solid material and disturbing, by a “dilution” effect, the exchange of the cationic element contained in the glass with the cationic element contained in the solid material.

For example, the protective film may be a film of Ni/Cr, Ti, Si or Ag. It is preferably deposited on the enamel by magnetron sputtering. The thickness of the film may vary from 100 nm to 1 μm, and is preferably between 150 and 300 nm.

According to one embodiment of the invention, the optical convergence zones, i.e. the high refractive index zones, are of rounded shape and merge on the free surface of the glazing that receives the solar flux (one example is shown in FIG. 5). In this case, it is advantageous to carry out the electric-field-assisted ion exchange from that surface of the glass exposed to the sun. Two procedures are then possible:
ion exchange from a bath of molten salt, such as AgNO₃, TlNO₃, etc., and through a masking film deposited on the surface of the glass. This film may for example be an Al, Ti, Ni/Cr or Al₂O₃ film deposited by sputtering, CVD, etc. The openings in the mask are circular and the ion exchange time is chosen so that the high-polarizability ions reach the opposite face of the glass;
ion exchange from a solid material containing the high-polarizability element. This material is deposited in the form of bands on the glazing surface, the thickness of the material deposited being chosen so that the high-polarizability ions reach the opposite face of the glass. This material may for example be an enamel deposited by screen printing.

Owing to the distortion of the electric field lines, the exchanged zone has a rounded shape, such as that desired for acting as an optical concentrator. The diameter of the circular openings in the masking film and the width of the bands of the solid material are approximately equal to the size of the active zones. The low refractive index zones are those that have not been affected by the ion exchange.

The principle of ion exchange in glass is itself known to those skilled in the art. The species to be exchanged migrate under the effect of an electric field applied by means of an electrode and a counterelectrode that are placed on either side of the glass substrate. The cationic elements migrate in one direction into the substrate. This means that the ions to be inserted into the glass arrive via one face, on the electrode side, whereas the ions expelled from the glass are expelled via the other face, on the counterelectrode side.

The electrode and the counterelectrode may consist of an ionic salt, a conductive enamel, at least as conductive as the substrate itself at the temperature of the exchange, or of a thin metallic or ceramic conductive film, such as one made of Ti, Ni/Cr, Al, ITO, SnO₂:F, etc.

According to one embodiment, bands of an enamel may be produced on the surface of the substrate. An enamel may be produced on the surface of the substrate using a glass frit, in a manner known to those skilled in the art. In particular, the firing of the enamel is carried out at a temperature above the melting point of the glass frit and below the softening temperature of the substrate. The firing time must be long enough for the glass frit to form a glassy matrix. As an illustration in the case of a substrate made of soda-lime-silica glass, the firing is carried out at a temperature not exceeding 700° C., preferably ranging from 600 to 680° C., for a time of less than 60 minutes, preferably 10 to 30 minutes. Depending on its conductivity, the enamel, in the form of bands placed on the electrode side, in addition to its ion source function, may itself act as electrode. In this case, it is desirable for the enamel to have the lowest possible porosity, or the highest compactness, so as to obtain the highest level of ion exchange.

If an enamel is used as counterelectrode, it may have a higher porosity.

If a molten salt is used as ion source, electrode or counterelectrode, the salt is preferably maintained at a temperature at least 10° C., and preferably at least 20° C., above its melting point.

The ion exchange is carried out in an electric field. The value of the electric field applied depends on the nature of the cationic elements to be exchanged and also on the composition of the substrate. In general, the electric field is chosen so as to obtain a rate of migration into the substrate of between 0.01 and 1 μm/min. This field is generally between 1 and 1000 volts per millimeter of thickness of the substrate.

If the zones are of trapezoidal shape, these zones are produced over at least one portion of the thickness of the substrate having a glass function, starting from a plane located at a given distance from that free surface of the substrate exposed to the sun.

The depth of the high refractive index zone is sufficient to allow total internal reflection of the light at the substrate/zone interface, toward the zones coated with the active film.

FIGS. 10 and 11 illustrate two embodiments of the invention, one in which the zones are produced over the entire thickness of the substrate (FIG. 10) and the other with the zones starting from a certain depth from the free surface (FIG. 11).

The orientation of the inclined sidewalls of the zones relative to the free surfaces of the substrate having a glass function is optimized at an angle θ of between 60° and 80°, more preferably between 65° and 75°, even more preferably substantially close to 70°, for an index difference n₂−n₁, between the high-index zone of index n₂ and the low-index zone of index n₁, of around 0.05 to 0.15, more particularly between 0.10 and 0.15, and for an incident light flux perpendicular to the free surface of the substrate having a glass function.

For this optimal angle, it may also be advantageous to optimize the aspect ratio of the optical concentrators. If l₁ is the longest length of the high-index zone in the plane located at a given depth from the free surface of the substrate having a glass function which is directed toward the light rays, and l₂ is the shortest length at that free surface of the substrate having a glass function which is directed toward the active zone for carrying out the energy conversion, then the concentration ratio is defined as the ratio l₁/l₂. The inverse ratio, namely l₂/l₁, corresponds to the percentage area coated with functional material relative to the area exposed to the solar radiation.

The low refractive index zones consist of the unexchanged glass substrate and may have a refractive index nₛ ranging from 1.3 to 2. The high refractive index zones may have a refractive index ranging from 1.43 to 2.13. In particular, a soda-lime glass has for example a refractive index n_{soda} of between 1.47 and 1.55. Silver-rich bands produced by the sodium contained in the glass being exchanged with silver coming from silver nitrate generally have a refractive index ranging from 1.01 n_{soda} to 1.2 n_{soda}.

Through the migration implemented in accordance with the invention, an ion that will replace another ion within a zone may replace it in an amount ranging from 10 to 100 mol %, generally more than 20 mol %.

The zones may equip a glazing in a concentrator application for a photovoltaic system. The glazing is generally inclined to the horizontal and a sun “tracking” system makes it possible to obtain angular configurations that ensure optimum energy conversion.

The glazing according to the invention is generally placed on a carrier structure positioned on a roof or on the ground, or else on a wall of a building (building of any type: dwelling, office, hangar, etc.) so that the glazing receives the sunlight.

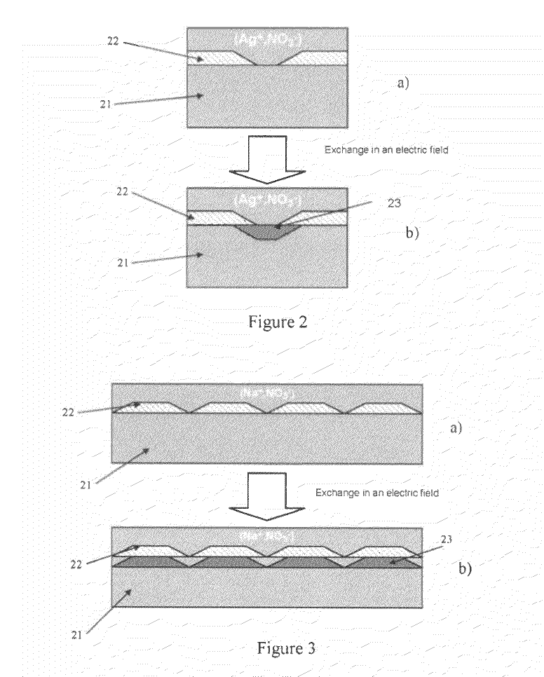

FIG. 2 shows the process for obtaining zones of trapezoidal shape starting from a solid containing the cationic element with which it is intended for a soda-lime glass to be locally enriched, in this example with a thickness of 2.1 mm, in order to create optical concentrators on its surface, over a certain depth.

Deposited on the surface of the glass 21 are glass bands 22 or frits of variable thickness, typically in the form of trapezoids, these frits being rich in Ag⁺. The whole assembly is immersed in a sodium nitrate bath (Na⁺, NO₃⁻) and subjected to an electric field.

The thickness profile of the Ag⁺-rich glass frit 22 is then reproduced in the glass by the Na⁺ ions being exchanged with the Ag⁺ ions so as to define zones 23 having a different refractive index from that of the surrounding medium and of substantially trapezoidal shape.

FIG. 4 shows horizontal glazing seen in cross section, provided with zones 23, especially of trapezoidal profile, along two intersecting directions thus defining an optical concentrator. The light rays coming from this source and penetrating the glass are reflected at the zone/medium interface and sent back toward the other face of the glazing, in a convergence zone bounded by the two sidewalls of the trapezoid. The incident light in the glazing in fact undergoes total internal reflection at the high-index zone/low-index zone interfaces and is thus redirected toward the end of the concentrator which is provided with an active surface for energy conversion.

In FIG. 4, the glass substrate has a thickness of 4 mm. The zones of index n₂ have for example a depth, starting from the first free surface, in the glass of 500 μm, a width l₁ of 700 μm at the incident-ray entry surface, and a width l₂ of 340 μm at the other end, at the small base of the trapezoid. In this figure, the sidewalls of the trapezoid are straight. In FIG. 5, the profile 20 of the high refractive index zones has a spherical or rounded envelope.

FIG. 6 illustrates the phenomenon of total internal reflection of a light ray at normal incidence to the surface of the glazing. The angle θ of the sidewalls of the zones is close to 70°, this value being the minimum angle for total reflection of the light for an index difference n₂−n₁ of 0.12 and at normal incidence.

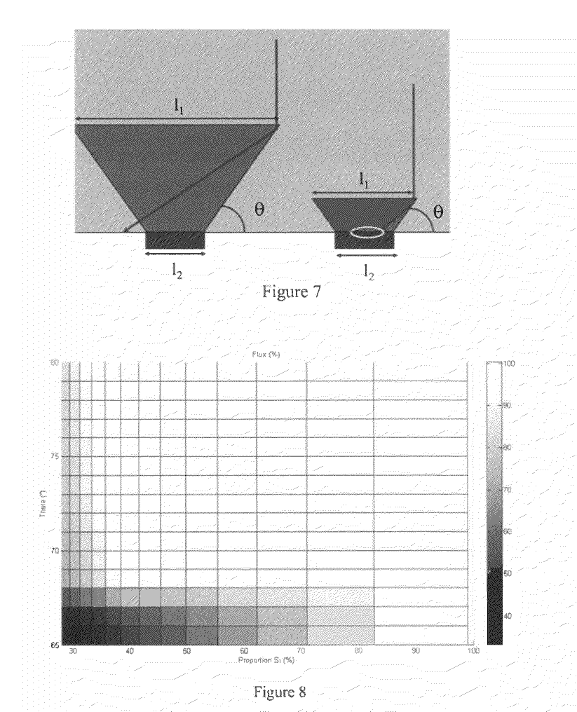

FIG. 7 illustrates two extreme cases of the ratio l₂/l₁.

On the left, too small a ratio results in the light rays not encountering any active surface and being lost.

On the right, in contrast, a high ratio enables all the incident light flux to be captured, but a portion of the active surface, namely the portion surrounded in FIG. 7, receives only the direct light, which means that the concentration factor may be further increased.

Optimization of the ratio l₂/l₁ may therefore be carried out.

As may be seen in FIG. 8, which shows the proportion of captured light flux to incident flux for various values of 0 of the structure and for various concentration ratios l₂/l₁, also corresponding to various proportions of active surface, i.e. surface coated with a material that can carry out the energy conversion, such as for example silicon, it should be noted that below an angle θₗᵢₘ between 65 and 70°, total reflection is not ensured and the captured flux drops sharply; that above this value θₗᵢₘ, increasing the angle θ does not significantly improve the performance of the system; and that for an l₂/l₁ ratio of around 40%, the captured light flux reaches practically 100%. This l₂/l₁ ratio therefore appears to be the optimum ratio.

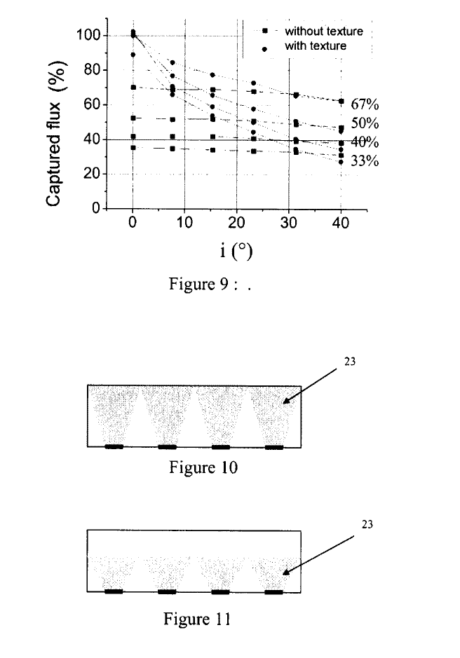

FIG. 9 shows the proportion of the flux captured by the photovoltaic cell as a function of the angle of incidence i in degrees of the light flux for various proportions of silicon deposited, with and without structure.

The table below summarizes, for an angle θ of 70° and an index difference n₂−n₁ of 0.13, the percentage solar flux captured, for two Si fill fractions, corresponding to respective l₂/l₁ ratios, and for three angles of incidence of the solar flux, these two fill fractions being 33% and 40% respectively, and the zones being of trapezoidal shape.

It should be noted that, without any structuring (i.e. in the absence of high-index and low-index zones), the light flux captured is equal to the Si fill fraction.

| Si fraction/ | | |
|---|---|---|
| Angle of incidence | 33% | 40% |
| 0° | 90% | 100% |
| 10 ° | 67% | 70% |
| 20 ° | 43% | 52% |

Compared with a substrate having no concentration zones, for which, for all angles of incidence, a captured flux value equal to the Si ratio is obtained, it should be noted that, for low angles of incidence and for these same Si ratios, captured flux values around twice as high are obtained with trapezoidal zones.

Of course, in the figures the various elements have not been drawn to scale for the sake of clarity.

### EXAMPLE 1

This example illustrates the embodiment described in relation to FIG. 2.

A substrate was formed from a soda-lime-silica glass composition comprising the constituents below, in the following proportions expressed in mol percent: 71% SiO₂; 13.5% Na₂O; 9.5% CaO; and 6% MgO. This substrate had a refractive index of 1.52.

An array of 400 trapezoidal bands, having a large base width of 100 μm, a small base width of 40 μm, a thickness of 20 μm, an angle θ of 70°, was deposited on one face of the substrate (measuring 5 cm×5 cm×3.1 mm), the bands being positioned edge to edge and formed by screen printing by means of an enamel composition comprising, in wt %:75% of silver particles; 10% of a glass frit; and 15% of a mixture of terpineols (a screen-printing medium providing the right viscosity for application on glass). The glass frit had the following composition, expressed in wt %:36% SiO₂; 30% Bi₂O₃; 24.5% Na₂O; 5.5% CaO; and 4% Al₂O₃.

The substrate coated with the screen-printed features was subjected to an enamel firing treatment at 650° C. for 30 minutes.

That face of the substrate bearing the enamel features was brought into contact with a molten (320° C.) NaNO₃ bath connected to the anode of an electrical voltage generator. The other face of the substrate was in contact with another molten (320° C.) NaNO₃ bath connected to the cathode of said generator. The ion exchange took place for 20 h with a potential difference applied between the terminals of the generator in such a way that the rate of migration of the Ag ions in the substrate was 0.07 μm/min.

The enamel was removed by acid etching for 5 min in a 68 wt % HNO₃ solution.

The depth of diffusion of the Ag ions into the glass at the features and the refractive index n₁ of the low-index zones and the refractive index n₂ of the high-index zones after ion exchange were measured on the substrate, namely:
diffusion depth: 84 μm;
n₁=1.52; n₂=1.63.

The existence of 84 μm-deep conical zones of trapezoidal profile in accordance with the initial profiles of the glass frit was observed.

### EXAMPLE 2

This example illustrates the variant of the invention in which the light concentration zone is of rounded shape and the depth of which is equal to the thickness of the glass.

A substrate was formed from a soda-lime-silica glass composition comprising the constituents below, in the following proportions expressed in mol percent: 71% SiO₂; 13.5% Na₂O; 9.5% CaO; and 6% MgO. This substrate had a refractive index of 1.52.

An array of 400 parallelepipedal bands with a width of 300 μm and a thickness of 100 μm was deposited on one face of the substrate (measuring 5 cm×5 cm×0.5 mm), said bands being formed by screen printing by means of an enamel composition comprising, in wt %:75% of silver particles; 10% of a glass frit; and 15% of a mixture of terpineols (a screen-printing medium providing the suitable viscosity for application on glass). The glass frit had the following composition, expressed in wt %: 36% SiO₂; 30% Bi₂O₃; 24.5% Na₂O; 5.5% CaO; and 4% Al₂O₃.

The substrate coated with the screen-printed features was subjected to an enamel firing treatment at 650° C. for 30 minutes. A metal electrode was then deposited on the other face of the glass. A positive voltage was applied to the screen-printed features, while the electrode on the opposite face was connected to ground.

The ion exchange took place for 120 h by applying a potential difference between the terminals of the generator in such a way that the average rate was 0.07 μm/min.

The refractive index n₂ of the high-index zones after ion exchange with silver was measured on the substrate, being equal to 1.63.

Moreover, it was found that the exchanged zones had a width of 1 mm on the screen-printed face and emerged on the opposite face over a width of 300 μm, with rounded edges on the sides.

1. A flat mineral glass comprising a first free surface and a second free surface, wherein the glass comprises a plurality of high-index zones having a high refractive index (n₂) and a plurality of low index zones having a low refractive index (n₁), which are formed in the thickness of the flat glass between a first free surface and a second free surface, over a depth of between 1 and 1000 μm starting from the first free surface, said high-index zones and low-index zones alternating along a direction transverse to the thickness direction of the flat glass between the first free surface and second free surface, the high-index zones flaring out from the first free surface toward the second free surface, and the envelope surfaces of the high-index zones making an angle (θ) of at least 65°, with respect to the first free surface.

2. The glass as claimed in claim 1, wherein the high-index zones are trapezoid-based prisms having a small base (l₂) and a large base (l₁), said prisms being formed over all or part of the thickness of the glass.

3. The glass as claimed in claim 1, wherein the high-index zones have a depth in the glass starting from the first free surface of between 20 μm and 700 μm.

4. The glass as claimed in claim 1, wherein the high-index zones have sidewalls with a rounded or spherical profile.

5. The glass as claimed in claim 1, wherein the refractive index difference, between the index (n₁) of each low-index zone and the index (n₂) of each high-index zone, is between 0.05 and 0.15.

6. The glass as claimed in claim 1, wherein the concentration ratio (l₂/l₁ is between 35 and 55%.

7. The glass as claimed in claim 1, wherein the high-index zones comprise at least one element selected from the group consisting of Ag, Tl, Cu, and Ba.

8. The glass as claimed in claim 1, wherein a solar concentrator provided with silicon bands is produced.

9. A photovoltaic module comprising a glass as claimed in claim 8.

10. A process of collecting light, incident toward a solar cell comprising contacting light to the glass of claim 1.

11. A process for fabricating the glass as claimed claim 1, comprising bringing a zone-free glass into contact with an alternation of bands of two different ion source materials providing different ions that can migrate into the glass under the effect of an electric field, and comprising the application of an electric field.

12. The glass fabrication process as claimed in claim 11, wherein the profile of the band conforms to the profile of the zone obtained in the glass after migration of the ions.

13. The process as claimed in claim 11, wherein at least one of the ion source materials is a solid and of the enamel type.
